(19) United States
(12) Patent Application Publication
(10) Pub. No.: US 2017/0084805 A1
(43) Pub. Date: Mar. 23, 2017

(54) OPTOELECTRONIC COMPONENT AND METHOD OF PRODUCING SAME

(71) Applicant: OSRAM Opto Semiconductors GmbH, Regensburg (DE)

(72) Inventors: Christian Gatzhammer, Lupburg (DE); Martin Brandl, Kelheim (DE); Tobias Gebuhr, Regensburg (DE)

(21) Appl. No.: 15/116,846

(22) PCT Filed: Feb. 3, 2015
(86) PCT No.: PCT/EP2015/052173

§ 371 Date: Aug. 5, 2016

(30) Foreign Application Priority Data
Feb. 7, 2014 (DE) 10 2014 101 557.6

(51) Int. Cl. H01L 33/62; H01L 25/075; H01L 33/48

(52) U.S. Cl. CPC H01L 33/62; H01L 33/483; H01L 25/0756; H01L 2933/0066

(57) ABSTRACT

An optoelectronic component includes an optoelectronic semiconductor chip including a first and second electrical contacts; a first leadframe section comprising a first chip contact pad and a first soldering contact pad situated opposite the first chip contact pad; and a second leadframe section including a second chip contact pad and a second soldering contact pad situated opposite the second chip contact pad, wherein the first electrical contact electrically conductively connects to the first chip contact pad and the second electrical contact electrically conductively connects to the second chip contact pad, a dielectric element is arranged between the first and second leadframe sections, the first and second leadframe sections and the dielectric element are embedded into a housing such that at least parts of the first and second soldering contact pads are accessible, and a surface of the dielectric element is exposed at the underside of the housing.

### TECHNICAL FIELD

This disclosure relates to an optoelectronic component and a method of producing an optoelectronic component.

### BACKGROUND

It is known that, in electronic and optoelectronic components provided for surface mounting (SMD components), mutually adjacent soldering contact pads should not fall below a minimum distance of 200 μm. Otherwise a coalescence of solder and hence an electrical short circuit between the electrical contact pads may occur during a soldering mounting of the component. It is further known to form electrical contact pads of SMD components by leadframe sections embedded into a plastic housing. Electronic and optoelectronic semiconductor chips of such components may be arranged on leadframe sections such that electrical contact pads of the semiconductor chips directly connect to the leadframe sections. Since the required minimum distance between the soldering contact pads in the prior art defines a minimum distance between the leadframe sections, this results in a minimum size of the semiconductor chip that obstructs further miniaturization.

### SUMMARY

We provide an optoelectronic component including an optoelectronic semiconductor chip including a first electrical contact and a second electrical contact, a first leadframe including a first chip contact pad and a first soldering contact pad situated opposite the first chip contact pad, and a second leadframe section including a second chip contact pad and a second soldering contact pad situated opposite the second chip contact pad, wherein the first electrical contact electrically conductively connects to the first chip contact pad and the second electrical contact electrically conductively connects to the second chip contact pad, a dielectric element is arranged between the first leadframe section and the second leadframe section, the first leadframe section, the second leadframe section and the dielectric element are embedded into a housing such that at least parts of the first soldering contact pad and the second soldering contact pad are accessible at an underside of the housing, and a surface of the dielectric element is exposed at the underside of the housing.

We also provide a method of producing an optoelectronic component including providing a first leadframe section including a first soldering contact pad and a second leadframe section including a second soldering contact pad, arranging a dielectric element between the first leadframe section and the second leadframe section, and embedding the first leadframe, the second leadframe section and the dielectric element into a housing such that at least parts of the first soldering contact pad and the second soldering contact pad remain accessible at an underside of the housing, and a surface of the dielectric element is exposed at the underside of the housing.

### BRIEF DESCRIPTION OF THE DRAWINGS

FIG. 1 shows a sectional side view of an optoelectronic component.

FIG. 2 shows a sectional side view of the optoelectronic component after a mounting on a circuit board.

### LIST OF REFERENCE SIGNS

10 Optoelectronic component
100 Optoelectronic semiconductor chip
101 Emission side
102 Contact side
110 First electrical contact
120 Second electrical contact
200 First leadframe section
210 First chip contact pad
220 First soldering contact pad
250 Distance
300 Second leadframe section
310 Second chip contact pad
320 Second soldering contact pad
400 Housing
401 Top side
402 Underside
410 Cavity
420 Potting material
500 Dielectric element
510 First section
511 Surface
512 Edge length
520 Second section
530 Third section
600 Circuit board
610 First soldering contact pad
620 Second soldering contact pad
630 Distance

### DETAILED DESCRIPTION

Our optoelectronic component comprises an optoelectronic semiconductor chip comprising a first electrical contact and a second electrical contact, a first leadframe section comprising a first chip contact pad and a first soldering contact pad situated opposite the first chip contact pad, and a second leadframe section comprising a second chip contact pad and a second soldering contact pad situated opposite the second chip contact pad. The first electrical contact electrically conductively connects to the first chip contact pad. The second electrical contact electrically conductively connects to the second chip contact pad. The first leadframe section and the second leadframe section are embedded into a housing such that at least parts of the first soldering contact pad and of the second soldering contact pad are accessible at an underside of the housing. A dielectric element is arranged between the first leadframe section and the second leadframe section. A surface of the dielectric element is exposed at the underside of the housing. Advantageously, the surface of the dielectric element at the underside of the housing of this optoelectronic component spatially separates the first soldering contact pad from the second soldering contact pad of the optoelectronic component, as a result of which a coalescence of solder and a resultant short circuit between the soldering contact pads of the optoelectronic component during a mounting of the optoelectronic component may be prevented.

The first chip contact pad and the second chip contact pad may comprise a distance of less than 200 μm. This makes it possible for the first electrical contact and the second electrical contact of the optoelectronic semiconductor chip of the optoelectronic component also to comprise a distance of less than 200 μm. As a result, the optoelectronic semiconductor chip of this optoelectronic component may advantageously have very small dimensions. A further advantage of the small distance between the first chip contact pad and the second chip contact pad is that the chip contact pads of the leadframe sections of the optoelectronic component may serve as a reflector for electromagnetic radiation emitted by the optoelectronic semiconductor chip in the direction of the chip contact pads of the leadframe sections. As a result of the small distance of less than 200 μm between the chip contact pads of the leadframe sections, only a small portion of the electromagnetic radiation passes between the first chip contact pad and the second chip contact pad, as a result of which a high proportion of the electromagnetic radiation is reflected. As a result, the optoelectronic component may advantageously have low light losses.

The surface of the dielectric element exposed at the underside of the housing may comprise an edge length of at least 200 μm. This advantageously ensures that the first soldering contact pad and the second soldering contact pad of the optoelectronic component also comprise a distance of at least 200 μm from one another. As a result, a coalescence of solder and a production of a short circuit between the first soldering contact pad and the second soldering contact pad of the optoelectronic component during a mounting of the optoelectronic component may advantageously be prevented.

The first soldering contact pad and the second soldering contact pad may terminate flush with the underside of the housing. Advantageously, the optoelectronic component is thereby suitable as an SMD component for a surface mounting, for example, for a surface mounting by reflow soldering.

The surface of the dielectric element exposed at the underside of the housing may terminate flush with the first soldering contact pad and the second soldering contact pad. Advantageously, the exposed surface of the dielectric element may thereby particularly effectively prevent a coalescence of solder between the first soldering contact pad and the second soldering contact pad of the optoelectronic component.

The dielectric element may be substantially optically transparent. Advantageously, as a result, absorption of electromagnetic radiation emitted by the optoelectronic semiconductor chip of the optoelectronic component in the dielectric element does not take place. Electromagnetic radiation having passed into the dielectric element may be reflected at one of the leadframe sections of the optoelectronic component and be made accessible for use as a result. As a result, the optoelectronic component may advantageously have a high efficiency.

The dielectric element may comprise a first section oriented parallel to the underside of the housing, a third section oriented parallel to the first chip contact pad, and a second section connecting the first section to the third section. The first section comprises the surface exposed at the underside of the housing. The third section is arranged between the first chip contact pad and the second chip contact pad. Advantageously, this example of the dielectric element enables distance between the first soldering contact pad and the second soldering contact pad of the optoelectronic component to be greater than the distance between the first chip contact pad and the second chip contact pad.

The second section may be oriented perpendicular to the first section. In this case, the first section and the third section extend in opposite spatial directions proceeding from the second section. By way of example, the first section may extend in the direction of the second leadframe section, while the third section extends in the direction of the first leadframe section. This advantageously results in an approximately z-shaped cross section of the dielectric element that makes it possible to arrange the first leadframe section and the second leadframe section of the optoelectronic component particularly close to one another without an excessively small distance between the first and second soldering contact pads.

The housing may comprise a cavity at a top side situated opposite the underside. In this case, at least parts of the first chip contact pad and of the second chip contact pad are accessible in the cavity. The optoelectronic semiconductor chip is arranged in the cavity. Advantageously, the cavity may serve as a reflector for electromagnetic radiation emitted by the optoelectronic semiconductor chip of the optoelectronic component. As a result, advantageously, a large portion of the electromagnetic radiation emitted by the optoelectronic semiconductor chip is emitted in a desired spatial direction by the optoelectronic component.

A potting material may be arranged in the cavity. The potting material may advantageously protect the optoelectronic semiconductor chip against damage as a result of external mechanical influences. The potting material may also comprise embedded converter particles that convert a wavelength of an electromagnetic radiation emitted by the optoelectronic semiconductor chip, or other embedded particles.

The first and second electrical contacts may be arranged on a common surface of the optoelectronic semiconductor chip. Advantageously, as a result, the optoelectronic semiconductor chip may electrically conductively connect to the leadframe sections of the optoelectronic component without the use of bond wires.

The optoelectronic semiconductor chip may be a volume emitting sapphire flip-chip. Advantageously, the optoelectronic semiconductor chip may comprise particularly compact dimensions as a result.

A method of producing an optoelectronic component comprises steps of providing a first leadframe section comprising a first soldering contact pad and a second leadframe section comprising a second soldering contact pad to arrange a dielectric element between the first leadframe section and the second leadframe section and embedding the first leadframe section and the second leadframe section into a housing such that at least parts of the first soldering contact pad and the second soldering contact pad remain accessible at an underside of the housing, and a surface of the dielectric element is exposed at the underside of the housing. Advantageously, the surface of the dielectric element exposed at the underside of the housing in the optoelectronic component obtainable by this method brings about a spatial separation of the first soldering contact pad from the second soldering contact pad of the optoelectronic component, making it possible to prevent a coalescence of solder and a resultant short circuit between the first and second soldering contact pads during mounting of the optoelectronic component obtainable by the method.

The method may comprise a further step of arranging an optoelectronic semiconductor chip in a cavity at a top side of the housing situated opposite the underside. Advantageously, in this case, an optoelectronic semiconductor chip comprising small external dimensions may be used, the electrical contacts of the chip being arranged close together.

Arranging the dielectric element between the first leadframe section and the second leadframe section may be performed by a molding method. As a result, the method is advantageously implementable simply and cost-effectively and is suitable for mass production.

The above-described properties, features and advantages and the way in which they are achieved will become clearer and more clearly understood in association with the following description of the examples explained in greater detail in association with the drawings.

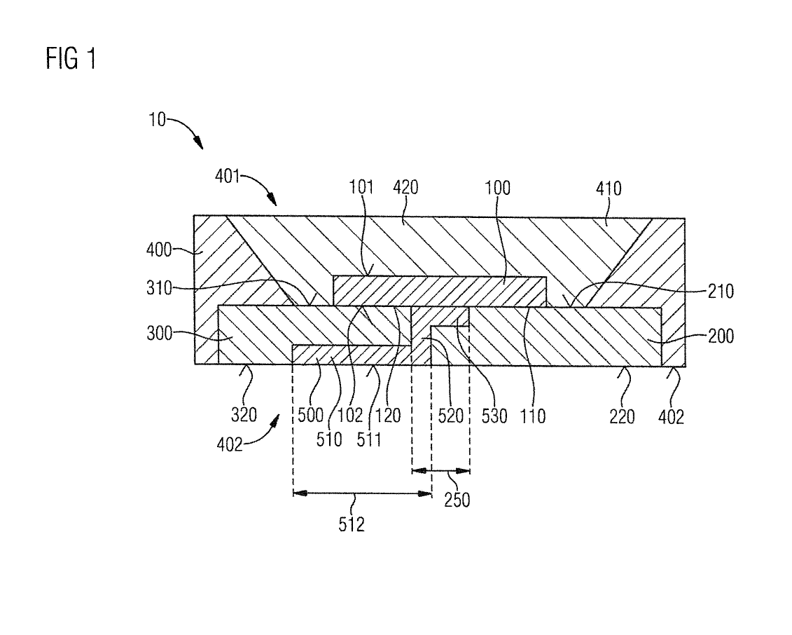

FIG. 1 shows a schematic sectional side view of an optoelectronic component 10. The optoelectronic component 10 emits electromagnetic radiation, for example, visible light. The optoelectronic component 10 may be a light emitting diode component (LED component), for example. The optoelectronic component 10 may also be designated as a package.

The optoelectronic component 10 comprises an optoelectronic semiconductor chip 100. The optoelectronic semiconductor chip 100 may be a light emitting diode chip (LED chip), for example. The optoelectronic semiconductor chip 100 is preferably a flip-chip, for example, a volume emitting sapphire flip-chip or a surface emitting flip-chip.

The optoelectronic semiconductor chip 100 comprises an emission side 101 and a contact side 102 situated opposite the emission side 101. A first electrical contact 110 and a second electrical contact 120 of the optoelectronic semiconductor chip 100 are arranged at the contact side 102 of the optoelectronic semiconductor chip 100. Via the electrical contacts 110, 120, an electrical voltage may be applied to the optoelectronic semiconductor chip 100 to cause the optoelectronic semiconductor chip 100 to emit electromagnetic radiation. The first electrical contact 110 may be an anode, for example. The second electrical contact 120 may be a cathode, for example. However, it is also possible for the first electrical contact 110 to be a cathode and the second electrical contact 120 to be an anode.

Electromagnetic radiation generated by the optoelectronic semiconductor chip 100 is emitted at the emission side 101 of the optoelectronic semiconductor chip 100. If the optoelectronic semiconductor chip 100 is a volume emitting semiconductor chip, then electromagnetic radiation is also emitted at other surfaces of the optoelectronic semiconductor chip 100 during operation of the optoelectronic semiconductor chip 100.

The optoelectronic component 10 comprises a first leadframe section 200 and a second leadframe section 300. The first leadframe section 200 and the second leadframe section 300 each comprise an electrically conductive material, preferably a metal. The first leadframe section 200 and the second leadframe section 300 may be formed from sections of a common leadframe during production of the optoelectronic component 10. The first leadframe section 200 and the second leadframe section 300 are spaced apart from one another and electrically insulated from one another.

The optoelectronic component 10 comprises a housing 400. The housing 400 comprises an electrically insulating housing material, preferably a plastic. By way of example, the housing material of the housing 400 may comprise an epoxy resin. The housing 400 is preferably produced by a molding method, for example, by injection molding. The housing 400 may be produced in a component assemblage with a multiplicity of further housings 400 of identical type and subsequently be singulated by separation from the further housings 400.

The first leadframe section 200 and the second leadframe section 300 are each at least partly embedded into the material of the housing 400. Preferably, the first leadframe section 200 and the second leadframe section 300 are already embedded into the material of the housing 400 during production of the housing 400. In this case, the leadframe sections 200, 300 may be embedded as parts of a continuous leadframe into a component assemblage comprising a plurality of housings 400, which is subsequently divided.

The first leadframe section 200 comprises a first chip contact pad 210 and a first soldering contact pad 220 situated opposite the first chip contact pad 210. The second leadframe section 300 comprises a second chip contact pad 310 and a second soldering contact pad 320 situated opposite the second chip contact pad 310.

The first soldering contact pad 220 of the first leadframe section 200 and the second soldering contact pad 320 of the second leadframe section 300 are at least partly not covered by the material of the housing 400, but rather are at least partly exposed at an underside 402 of the housing 400. In this case, the first soldering contact pad 220 and the second soldering contact pad 320 are arranged laterally alongside one another at the underside 402 of the housing 400. Preferably, the first soldering contact pad 220 and the second soldering contact pad 320 terminate substantially flush with the underside 402 of the housing 400. The first soldering contact pad 220 and the second soldering contact pad 320 form electrical connection pads of the optoelectronic component 10 and are provided for electrical contact during a mounting of the optoelectronic component 10. The optoelectronic component 10 may be provided, for example, as an SMD component for a surface mounting. An electrical contacting of the soldering contact pads 220, 320 of the optoelectronic component 10 during a mounting of the optoelectronic component 10 may be performed, for example, by reflow soldering.

The housing 400 comprises a cavity 410 at a top side 401 of the housing 400 situated opposite the underside 402. The cavity 410 is a depression at the top side 401 of the housing 400. At the bottom of the cavity 410, parts of the first chip contact pad 210 of the first leadframe section 200 and of the second chip contact pad 310 of the second leadframe section 300 are accessible and not covered by the material of the housing 400.

In the cavity 410 of the housing 400 of the optoelectronic component 10, the optoelectronic semiconductor chip 100 is arranged above the first chip contact pad 210 and second chip contact pad 310. In this case, the contact side 102 of the optoelectronic semiconductor chip 100 faces the chip contact pads 210, 310. The first electrical contact 110 at the contact side 102 of the optoelectronic semiconductor chip 100 electrically conductively connects to the first chip contact pad 210 of the first leadframe section 200. The second electrical contact 120 at the contact side 102 of the optoelectronic semiconductor chip 100 electrically conductively connects to the second chip contact pad 310 of the second leadframe section 300. The electrically conductive connections between the electrical contacts 110, 120 of the optoelectronic semiconductor chip 100 and the chip contact pads 210, 310 of the leadframe sections 200, 300 may be soldering connections, for example.

A potting material 420 is arranged in the cavity 410 of the housing 400 of the optoelectronic component 10. The optoelectronic semiconductor chip 100 is embedded into the potting material 420. The potting material 420 is preferably substantially transparent for electromagnetic radiation emitted by the optoelectronic semiconductor chip 100. The potting material 420 may comprise a silicone, for example. The potting material 420 may protect the optoelectronic semiconductor chip 100 against damage as a result of external mechanical influences. The potting material 420 may additionally comprise embedded converter particles that convert the wavelength of electromagnetic radiation emitted by the optoelectronic semiconductor chip 100. By way of example, the converter particles embedded into the potting material 420 may be configured to convert electromagnetic radiation having a wavelength from the blue or ultraviolet spectral range emitted by the optoelectronic semiconductor chip 100 into white light. The wavelength-converting particles embedded into the potting material 420 may comprise, for example, an organic phosphor, an inorganic phosphor or quantum dots.

In addition or as an alternative to wavelength-converting particles embedded into the potting material 420, scattering particles may also be embedded into the potting material 420, the scattering particles scattering electromagnetic radiation emitted by the optoelectronic semiconductor chip 100. However, the particles embedded into the potting material 420 or else the potting material 420 may be omitted.

A dielectric element 500 is arranged between the first leadframe section 200 and the second leadframe section 300. The dielectric element 500 is likewise embedded into the material of the housing 400. The dielectric element 500 comprises a dielectric material. Preferably, the dielectric element 500 is optically substantially transparent for electromagnetic radiation emitted by the optoelectronic semiconductor chip 100 of the optoelectronic component 10.

The dielectric element 500 is preferably arranged between the first leadframe section 200 and the second leadframe section 300 already before embedding the first leadframe section 200 and the second leadframe section 300. By way of example, the dielectric element 500 may be arranged between the first leadframe section 200 and the second leadframe section 300 by a molding method. Afterward, the leadframe sections 200, 300 and the dielectric element 500 are jointly embedded into the material of the housing 400.

A surface 511 of the dielectric element 500 is exposed at the underside 402 of the housing 400. The surface 511 of the dielectric element 500 exposed at the underside 402 of the housing 400 is arranged between the first soldering contact pad 220 and the second soldering contact pad 320. Preferably, the surface 511 of the dielectric element 500 terminates substantially flush with the first soldering contact pad 220 and the second soldering contact pad 320.

In the connection direction between the first soldering contact pad 220 of the first leadframe section 200 and the second soldering contact pad 320 of the second leadframe section 300, the surface 511 of the dielectric element 500 exposed at the underside 402 of the housing 400 comprises an edge length 512. As a result, the first soldering contact pad 220 and the second soldering contact pad 320 comprise a distance from one another which is at least of the same magnitude as the edge length 512 of the surface 511 of the dielectric element 500. Preferably, the edge length 512 is at least 200 μm. Consequently, the first soldering contact pad 220 and the second soldering contact pad 320 of the optoelectronic component 10 also comprise a distance of at least 200 μm from one another. This advantageously prevents solder from coalescing and causing a short circuit between the soldering contact pads 220, 320 of the optoelectronic component 10 during a mounting of the optoelectronic component 10.

At the bottom of the cavity 410 between the first chip contact pad 210 and the second chip contact pad 310, a further surface of the dielectric element 500 is exposed and preferably terminates substantially flush with the first chip contact pad 210 and the second chip contact pad 310. The surface of the dielectric element 500 exposed at the bottom of the cavity 410 is arranged between the first chip contact pad 210 and the second chip contact pad 310.

The first chip contact pad 210 of the first leadframe section 200 and the second chip contact pad 310 of the second leadframe section 300 comprise a distance 250 from one another. Preferably, the surface of the dielectric element 500 exposed at the bottom of the cavity 410 comprises, in the connection direction between the first chip contact pad 210 and the second chip contact pad 310, an edge length that substantially corresponds to the distance 250. Preferably, the distance 250 between the first chip contact pad 210 and the second chip contact pad 310 is less than 200 μm.

The first electrical contact 110 and the second electrical contact 120 at the contact side 102 of the optoelectronic semiconductor chip 100 may then also comprise a distance of less than 200 μm from one another. This makes it possible for the entire optoelectronic semiconductor chip 100 to have an edge length of less than 200 μm. The dielectric element 500 comprises a first section 510, a second section 520 and a third section 530. The first section 510 of the dielectric element 500 is oriented parallel to the underside 402 of the housing 400 and comprises the surface 511 exposed at the underside 402 of the housing 400. In the region of the first portion 510 of the dielectric element 500, the second leadframe section 300 is thinned in a direction perpendicular to the second soldering contact pad 320 such that a rear side of the second leadframe section 300 situated opposite the second chip contact pad 310 of the second leadframe section 300, in the region of the first section 510 of the dielectric element 500, is set back relative to the second soldering contact pad 320 of the second leadframe section 300. The first section 510 of the dielectric element 500 extends along the set-back rear side of the second leadframe section 300 in this region of the second leadframe section 300.

The third section 530 of the dielectric element 500 is oriented parallel to the first chip contact pad 210 of the first leadframe section 200 and comprises the surface of the dielectric element 500 exposed at the bottom of the cavity 410 of the housing 400. In the region of the third section 530 of the dielectric element 500, the first leadframe section 200 is thinned relative to the other sections of the first leadframe section 200 such that a front side of the first leadframe section 200 situated opposite the first soldering contact pad 220 of the first leadframe section 200, in the region of the third section 530 of the dielectric element 500, is set back relative to the first chip contact pad 210 of the first leadframe section 200. The third section 530 of the dielectric element 500 extends along the set-back front side of the first leadframe section 200 in this region.

The second section 520 of the dielectric element 500 connects the first section 510 to the third section 530 of the dielectric element 500. In this case, the second section 520 of the dielectric element 500 is oriented perpendicular to the first section 510 and perpendicular to the third section 530. The first section 510 and the third section 530 of the dielectric element 500 extend in mutually opposite spatial directions proceeding from the second section 520 of the dielectric element 500. In a sectional view perpendicular to the underside 402 of the housing 400 running through the first leadframe section 200 and the second leadframe section 300, the dielectric element 500 is thus approximately in a z-shape. However, the dielectric element 500 could also be shaped differently. In particular, the third section 530 of the dielectric element 500 could be omitted.

The surfaces of the first leadframe section 200 and the second leadframe section 300, in particular the chip contact pads 210, 310, may have a high reflectivity for electromagnetic radiation emitted by the optoelectronic semiconductor chip 100 of the optoelectronic component 10. By way of example, the surfaces of the leadframe sections 200, 300 may be silver-coated. As a result, electromagnetic radiation emitted by the optoelectronic semiconductor chip 100 in the direction of the underside 402 of the housing 400 is reflected at the surfaces of the leadframe sections 200, 300, as a result of which the electromagnetic radiation may subsequently be coupled out at the top side 401 of the housing 400. Light losses within the optoelectronic component 10 are avoided as a result. Electromagnetic radiation impinging on the dielectric element 500 in the region of the third section 530 of the dielectric element 500 may penetrate through the transparent dielectric element 500 and is subsequently reflected at the set-back front side of the first leadframe section 200, as a result of which these radiation portions may also subsequently be coupled out from the optoelectronic component 10 at the top side 401 of the housing 400. Owing to the only very small distance between the first leadframe section 200 and the second leadframe section 300, light losses may be kept very small in the optoelectronic component 10.

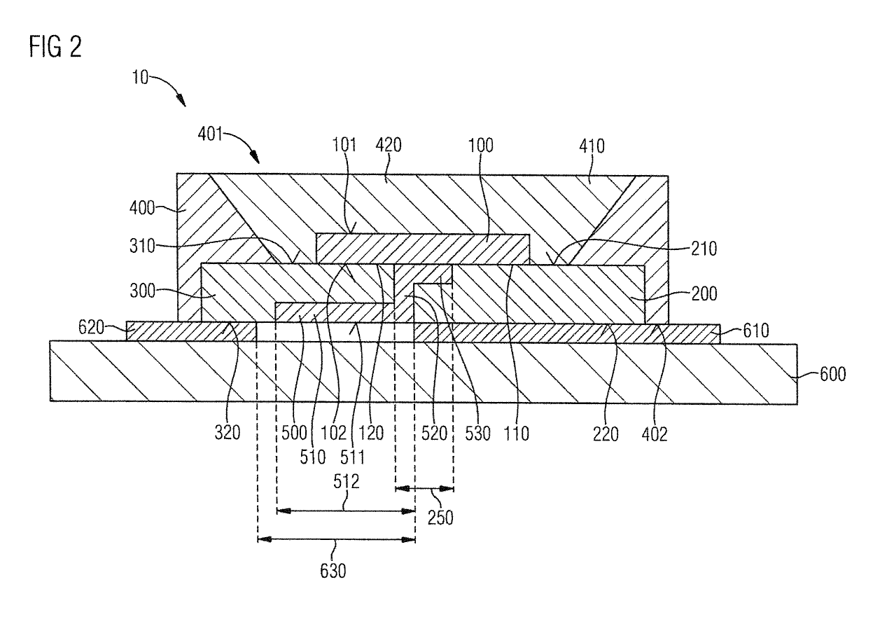

FIG. 2 shows a schematic sectional side view of the optoelectronic component 10 after a mounting of the optoelectronic component 10 on a top side of a circuit board 600. The circuit board 600 may also be designated as a printed circuit board or as a PCB. The circuit board 600 may serve as a carrier for further electronic components and circuits not shown in the schematic illustration in FIG. 2.

A first soldering contact pad 610 and a second soldering contact pad 620 are arranged at the surface of the circuit board 600. The first soldering contact pad 610 and the second soldering contact pad 620 may connect to further circuit parts via lines (not illustrated). The first soldering contact pad 610 and the second soldering contact pad 620 comprise a distance 630 from one another. The distance 630 preferably approximately corresponds to the distance between the first soldering contact pad 220 and the second soldering contact pad 320 of the optoelectronic component 10 and thus also approximately corresponds to the edge length 512 of the surface 511 of the dielectric element 500 exposed at the underside 402 of the housing 400 of the optoelectronic component 10. In particular, the distance 630 between the soldering contact pads 610, 620 is preferably at least 200 μm to reliably prevent a coalescence of solder between the first soldering contact pad 610 and the second soldering contact pad 620.

The optoelectronic component 10 is arranged at the top side of the circuit board 600. The underside 402 of the housing 400 of the optoelectronic component 10 faces the top side of the circuit board 600. The first soldering contact pad 220 of the first leadframe section 200 electrically conductively connects to the first soldering contact pad 610 of the circuit board 600. The second soldering contact pad 320 of the second leadframe section 300 of the optoelectronic component 10 electrically conductively connects to the second soldering contact pad 620 of the circuit board 600. The soldering contact pads 220, 320 of the optoelectronic component 10 may be connected to the soldering contact pads 610, 620 of the circuit board 600, for example, by reflow soldering or some other method of surface mounting. In this case, the distance 630 between the soldering contact pads 610, 620 of the circuit board 600 and the spacing apart of the first soldering contact pad 220 and the second soldering contact pad 320 of the optoelectronic component 10 prevented a coalescence of solder between the first soldering contact pads 220, 610 and the second soldering contact pads 320, 620 and a resultant short circuit.

Our components and methods have been illustrated and described in greater detail on the basis of the preferred examples. Nevertheless, this disclosure is not restricted to the examples disclosed. Rather, other variations may be derived therefrom by those skilled in the art, without departing from the scope of protection of the appended claims.

This application claims priority of DE 10 2014 101 557.6, the subject matter of which is hereby incorporated by reference.

1-15. (canceled)

16. An optoelectronic component comprising:
an optoelectronic semiconductor chip comprising:
a first electrical contact and a second electrical contact;
a first leadframe section comprising a first chip contact pad and a first soldering contact pad situated opposite the first chip contact pad; and
a second leadframe section comprising a second chip contact pad and a second soldering contact pad situated opposite the second chip contact pad,
wherein
the first electrical contact electrically conductively connects to the first chip contact pad and the second electrical contact electrically conductively connects to the second chip contact pad,
a dielectric element is arranged between the first leadframe section and the second leadframe section,
the first leadframe section, the second leadframe section and the dielectric element are embedded into a housing such that at least parts of the first soldering contact pad and the second soldering contact pad are accessible at an underside of the housing, and
a surface of the dielectric element is exposed at the underside of the housing.

17. The optoelectronic component according to claim 16, wherein the first chip contact pad and the second chip contact pad comprise a distance of less than 200 μm.

18. The optoelectronic component according to claim 16, wherein the surface of the dielectric element exposed at the underside of the housing comprises an edge length of at least 200 μm.

19. The optoelectronic component according to claim 16, wherein the first soldering contact pad and the second soldering contact pad terminate flush with the underside of the housing.

20. The optoelectronic component according to claim 16, wherein the surface of the dielectric element exposed at the underside of the housing terminates flush with the first soldering contact pad and the second soldering contact pad.

21. The optoelectronic component according to claim 16, wherein the dielectric element is substantially optically transparent.

22. The optoelectronic component according to claim 16,
wherein the dielectric element comprises a first section oriented parallel to the underside of the housing, a third section oriented parallel to the first chip contact pad, and a second section connecting the first section to the third section,
the first section comprises the surface exposed at the underside of the housing, and
the third section is arranged between the first chip contact pad and the second chip contact pad.

23. The optoelectronic component according to claim 22,
wherein the second section is oriented perpendicular to the first section, and
the first section and the third section extend in opposite spatial directions proceeding from the second section.

24. The optoelectronic component according to claim 16,
wherein the housing comprises a cavity at a top side situated opposite the underside,
at least parts of the first chip contact pad and the second chip contact pad are accessible in the cavity, and
the optoelectronic semiconductor chip is arranged in the cavity.

25. The optoelectronic component according to claim 24, wherein a potting material is arranged in the cavity.

26. The optoelectronic component according to claim 16, wherein the first electrical contact and the second electrical contact are arranged on a common surface of the optoelectronic semiconductor chip.

27. The optoelectronic component according to claim 26, wherein the optoelectronic semiconductor chip is a volume emitting sapphire flip-chip.

28. A method of producing an optoelectronic component comprising:
providing a first leadframe section comprising a first soldering contact pad and a second leadframe section comprising a second soldering contact pad;
arranging a dielectric element between the first leadframe section and the second leadframe section; and
embedding the first leadframe section, the second leadframe section and the dielectric element into a housing such that at least parts of the first soldering contact pad and the second soldering contact pad remain accessible at an underside of the housing, and a surface of the dielectric element is exposed at the underside of the housing.

29. The method according to claim 28, further comprising arranging an optoelectronic semiconductor chip in a cavity at a top side of the housing situated opposite the underside.

30. The method according to claim 28, wherein arranging the dielectric element between the first leadframe section and the second leadframe section is performed by a molding method.
